(19) United States
(12) Patent Application Publication
(10) Pub. No.: US 2024/0357808 A1
(43) Pub. Date: Oct. 24, 2024

(54) MEMORY DEVICE AND MANUFACTURING METHOD OF THE SAME

(71) Applicant: Ipcell Corporation Limited, Hong Kong (HK)

(72) Inventor: Te-Hsun HSU, Hsinchu County (TW)

(21) Appl. No.: 18/430,675

(22) Filed: Feb. 2, 2024

(30) Foreign Application Priority Data
Apr. 24, 2023 (CN) 202310449448.0

(51) Int. Cl. H10B 41/70; H10B 41/35

(52) U.S. Cl. CPC H10B 41/70; H10B 41/35

(57) ABSTRACT

The present disclosure relates to a memory device including a gate erased region and a floating gate transistor. The erased gate region includes a first well. The floating gate transistor includes a first channel area and a second channel area that are arranged in a first direction and a floating gate structure arranged above the first channel area and the second channel area. The floating gate structure extends over the first well in a second direction. The first channel region and the second channel region have different channel formation critical voltages. With the memory device provided by the present disclosure, the erase voltage applied to the erased gate region is reduced to prevent the semiconductor junction from collapsing, thereby improving the reliability of the memory device.

### CROSS-REFERENCE TO RELATED APPLICATION

This application claims priority to China Application Serial Number 202310449448.0, filed Apr. 24, 2023, which is herein incorporated by reference in its entirety.

### BACKGROUND

### Field of Invention

The present disclosure relates to a memory device and a manufacturing method of the same. More particularly, the present disclosure relates to a memory device which has different critical voltages of channel formation, and a manufacturing method of the same.

### Description of Related Art

The erasable programmable nonvolatile memory has been widely applied in various kinds of circuits. With the advancement of fabrication techniques, the nonvolatile memory with a polysilicon layer as its floating gate has reduced the difficulties and steps of manufacturing. However, the reliability of the memory device is still under threat due to the excessively high operation voltage.

### SUMMARY

A memory device according to one embodiment of the present disclosure is provided and has the following elements: the first well; the first doped region disposed in the first well and coupled to an erasure signal line, and having the first conducting type; the second doped region disposed in the second well and coupled to a bit line, and having the second conducting type; a floating gate structure crossing above the first well and the second well, and the floating gate structure including the first gate structure having the first capacitive coupling ratio, and the second gate structure. The first gate structure and the second gate structure are disposed above the second well, and the second gate structure has the second capacitive coupling ratio that is different from the first capacitive coupling ratio.

In some embodiments, the first gate structure has the second conducting type and the second gate structure is an undoped region.

In some embodiments, the first gate structure has the second conducting type and the second gate structure has the first conducting type.

In some embodiments, the memory device further includes the first channel region under the first gate structure and the second channel region under the second gate structure. The first channel region and the second channel region have different doping concentrations.

In some embodiments, the distance between the first gate structure and the first doped region is smaller than the distance between the second gate structure and the first doped region, and the first capacitive coupling ratio is smaller the second capacitive coupling ratio.

In some embodiments, the floating gate structure further includes the third gate structure disposed above the first well and having the third capacitive coupling ratio. The third capacitive coupling ratio is smaller than the first capacitive coupling ratio.

In some embodiments, along the first direction, the first gate structure has the first width and the second gate structure has the second width different from the first width.

In some embodiments, during an erasure operation, the absolute values of the voltage at the erasure signal line and the voltage at the bit line are the same.

According to another embodiment of the present disclosure, a memory device is provided and has an erasure gate region and a floating gate transistor. The erasure gate region includes the first well. The floating gate transistor includes the first channel region and the second channel region that are disposed along the first direction, and the floating gate structure disposed above the first channel region and the second channel region. The floating gate structure extends above the first well along the second direction. The first channel region and the second channel region have different critical voltages of channel formation.

In some embodiments, the absolute value of the critical voltage of channel formation of the first channel region is smaller than the absolute value of the critical voltage of channel formation of the second channel region.

In some embodiments, the area of the first channel region under the floating gate structure is smaller than the area of the second channel region under the floating gate structure.

In some embodiments, the floating gate structure includes the first gate structure and the second gate structure. The first gate structure is disposed above the first channel region and has the first width along the first direction. The second gate structure is disposed above the second channel region and has the second width which, along the first direction, is greater than the first width. The first gate structure and the second gate structure have different doping concentrations.

In some embodiments, the floating gate structure includes the first doped region. The first doped region is disposed in the second well and configured to receive the bit line voltage. The first channel region is disposed between the first doped region and the second channel region. The first doped region and the first gate structure have the same conducting type.

In some embodiments, the first gate structure has the first conducting type and the second gate structure has the second conducting type that is different from the first conducting type.

In some embodiments, the erasure gate region further includes the second doped region disposed in the first well and configured to receive the erasure voltage. During erasure operation, the erasure voltage may be a positive voltage and the bit line voltage may be a negative voltage.

In some embodiments, the first channel region and the second channel region have different doping concentrations.

In some embodiments, along the first direction, the first channel region has the first width and the second channel region has the second width which is greater than the first width.

According to another embodiment of the present disclosure, a manufacturing method of the memory device is provided and includes the following steps. The first doped region is formed in the first well. A gate dielectric layer extending along the first direction on the first well and the second well is formed, wherein the gate dielectric layer covers the first channel region and the second channel region that are disposed along the second direction which is different from the first direction. A floating gate structure is formed on the gate dielectric layer. The floating gate structure includes the first portion overlapping the first channel region and the second portion overlapping the second channel region in a planar view, and, in the planar view, the first channel region is between the first doped region and the second channel region. The first capacitive coupling ratio of the first portion to the first doped region is different from the second capacitive coupling ratio of the second portion to the first well.

In some embodiments, the first portion is P-conducting type and the second portion is N-conducting type.

In some embodiments, the manufacturing method further includes a following step. The second doped region, which is different from the first well, is formed as the second channel region in the first well.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of the memory device in a planar view according to some embodiments.

FIG. 2A is a perspective diagram corresponding to one portion of the memory device in FIG. 1 along line AA′ according to one embodiment.

FIG. 2B is a perspective diagram corresponding to one portion of the memory device in FIG. 1 along line BB′ according to one embodiment.

FIG. 2C is a perspective diagram corresponding to one portion of the memory device in FIG. 1 along line CC′ according to one embodiment.

FIG. 3 is a schematic diagram of a circuit of the memory device according to one embodiment.

FIG. 4 is a perspective diagram corresponding to portions of the memory device in FIG. 1 along lines DD′, EE′, FF′ according to one embodiment.

FIG. 5A is a perspective diagram corresponding to the memory device in FIG. 1 under operation according to one embodiment.

FIG. 5B is a perspective diagram corresponding to the memory device in FIG. 1 under operation according to one embodiment.

FIG. 6A is a perspective diagram corresponding to a portion of the memory device in FIG. 1 under operation according to one embodiment.

FIG. 6B is a perspective diagram corresponding to a portion of the memory device in FIG. 1 according to another embodiment.

FIG. 6C is a perspective diagram corresponding to a portion of the memory device in FIG. 1 according to another embodiment.

FIG. 7 is a flowchart of a manufacturing method of a memory device according to one embodiment.

FIG. 8 is a perspective diagram corresponding to one portion of the memory device in FIG. 1 along line GG′ according to another embodiment.

FIG. 9 is a schematic diagram corresponding to the memory device in a planar view in FIG. 1 according to another embodiment.

FIG. 10 is a schematic diagram corresponding to the memory device in the planar view in FIG. 1 according to another embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

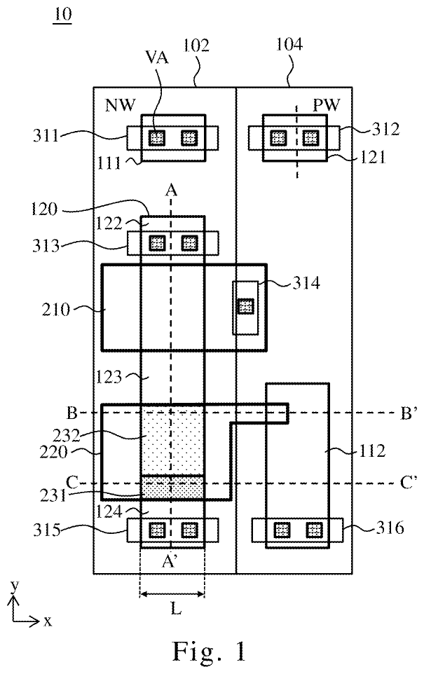

Please refer to FIG. 1. FIG. 1 is a schematic diagram of a memory device 10 in a planar view according to one embodiment. As shown in FIG. 1, the memory device 10 includes a well 102 of N-conducting type and a well 104 of P-conducting type that both extend in the y direction. The wells 102, 104 are adjacent to each other. The memory device 10 further includes an active region 120 extending in the y direction, a gate structure 210 extending in the x direction, a floating gate structure 220, multiple vias VA and multiple conducting segments 311-316 configured to transmit signals. The active region 120 includes doped regions 111, 122-124 that are in the well 102, and doped regions 112, 121 in the well 104.

In some embodiments, the wells 102 and 104 and the doped regions 111-112, 121-124 are in the first semiconducting layer. The gate structure 210 and the floating gate structure 220 are in the second semiconducting layer above the first semiconducting layer. The conducting segments 311-316 are in the third semiconducting layer above the second semiconducting layer. The vias VA are disposed between one of the doped regions 111-112, 121-124 and one of the conducting segments 311-316, and disposed between the gate structure 210 and the conducting segment 314.

In the embodiment of FIG. 1, the doped regions 111 and 112 are N-conducting type (labelled as N+) and the doped regions 121-124 are P-conducting type (labelled as P+). In some embodiments, the regions of N-conducting type are doped with n-type dopants, including Phosphorus, Arsenic, or combinations of the same. The regions of P-conducting type are doped with p-type dopants, including Boron, Indium, Aluminum, Gallium, or combinations of the same.

In some embodiments, the doped region 111 is configured as a pickup of the well 102 to receive voltages (for example, a voltage VNW shown in FIG. 3) for the well 102 through the vias VA and the conducting segment 311. Similarly, the doped region 121 is configured as a pickup of the well 104 to receive voltages (as the voltage VPW shown in FIG. 3) for the well 104 through the vias VA and the conducting segment 312.

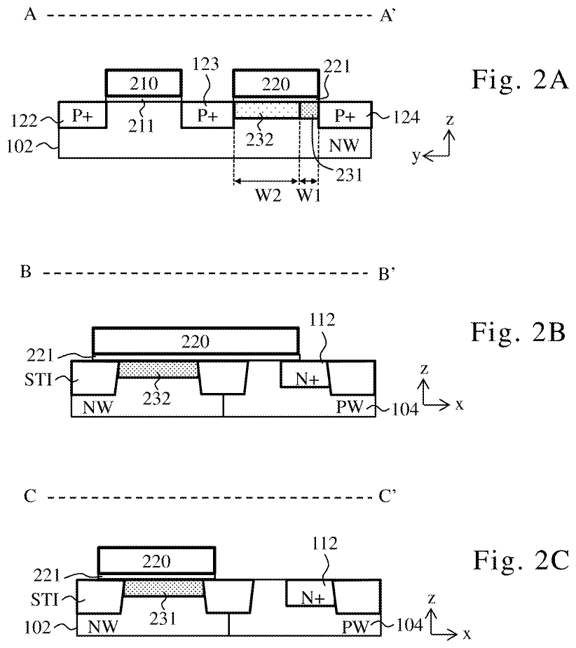

Reference is now made to FIG. 1 and FIG. 2A to FIG. 2C at the same time. FIG. 2A to FIG. 2C are perspective diagrams respectively corresponding to one portion of the memory device 10 in FIG. 1 along lines AA′, BB′, CC′ according to one embodiment.

As shown in FIG. 2A, a gate dielectric layer 211 is formed between the gate structure 210 and the well 102. Channel regions 231 and 232 that are in the active region 120 under the floating gate structure 220 and the gate dielectric layer 221 and in the well 102 are disposed along the y direction. The channel region 231 is disposed between the doped region 124 and the channel region 232, and the channel region 232 is disposed between the doped region 123 and the channel region 231. The channel regions 231 and 232 have different widths W1 and W2 along the y direction. In some embodiments, the width W2 is greater than the width W1. As shown in FIG. 1, when the active region 120 has a length L, the area of the channel region 231 under the floating gate structure 220 is smaller than the area of the channel region 232 under the floating gate structure 220.

In FIG. 2B, the portion of the floating gate structure 220 extending along the x direction crosses above the wells 102 and 104, and the floating gate structure 220 and the gate dielectric layer 221 extend further above the doped region 112. The memory device 10 includes multiple shallow trench isolations STIs that partially separate the wells 102 and 104, and separate the channel regions 231 and 232 and the well 104.

According to some other embodiments, the floating gate structure 220 and the gate dielectric layer 221 may be aligned with the boundary of the doped region 112.

In addition, reference is made to some other embodiments, a lightly-doped drain (LDD) implant region under the LDD spacer may be in the well 104, and the LDD implant region may be adjacent to the doped region 112. In these embodiments, the floating gate structure 220 and the gate dielectric layer 221 may be aligned with the boundary of the LDD implant region. In some embodiments, the doping concentration of the doped region 112 may be higher than the doping concentration of the LDD implant region.

In FIG. 2C, the channel region 231 is disposed between two adjacent shallow trench isolations STIs.

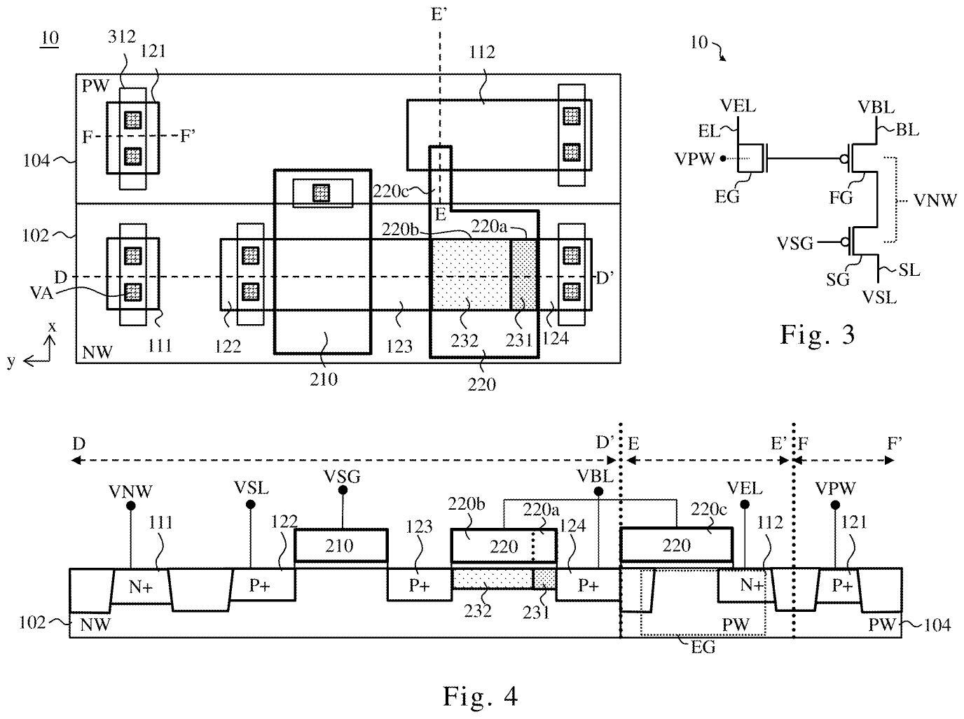

Reference is made to FIG. 3 and FIG. 4. FIG. 3 is a schematic diagram of the circuit of the memory device 10 according to one embodiment. FIG. 4 is a perspective diagram corresponding to portions of the memory device 10 in FIG. 1 along lines DD′, EE′, FF′ according to one embodiment.

As shown in FIG. 3, the memory device 10 includes an erasure gate region EG, and a selecting transistor SG and a floating gate transistor that are p-type and coupled in series. In some embodiments, the memory device 10 may be implemented as an erasable programmable nonvolatile memory. The selecting transistor SG is configured to be turned on or off in response to a selecting voltage VSG received by the gate thereof, one end of the selecting transistor SG (e.g., the source) is coupled to a source line SL to receive a source line voltage VSL, and the other end is coupled to one end of the floating gate transistor FG. The drain of the floating gate transistor FG receives the bit line voltage VBL through the bit line BL and the gate of the floating gate transistor FG is coupled to one end of the erasure gate region EG. One end of the erasure gate region EG receives an erasure voltage VEL by the erasure signal line EL. In some embodiments, the erasure gate region EG is configured as a capacitor to store carriers (e.g., electrons) flowing from the floating gate transistor FG.

Reference is made to FIG. 3 and FIG. 4 at the same time. In some embodiments, the well 102 corresponds to the body of the floating gate transistor FG and the body of the selecting transistor SG, and receives the voltage VNW through the doped region 111. The doped region 122 corresponds to the source of the selecting transistor SG and receives the source line voltage VSL through the conducting segment 313. The gate structure 210 corresponds to the gate of the selecting transistor SG and receives the selecting voltage VSG. The doped region 123 corresponds to a node at which the selecting transistor SG and the floating gate transistor FG are coupled. The doped region 124 corresponds to the drain of the floating gate transistor FG and receives the bit line voltage VBL through the conducting segment 315. The erasure gate region EG includes the well 104 configured to receive the voltage VPW and the doped region 112 receiving the erasure voltage VEL through the conducting segment 316.

In some embodiments, the memory device 10 may conduct at least 3 kinds of operation by controlling the voltages received by the floating gate transistor FG, the selecting transistor SG and the erasure gate transistor, three operations including program, erasure and read as shown in the following table 1.

TABLE 1
Voltages of the memory device 10 under different operations

| Operation | | VSG | VBL | VSL | VNW | VEL | VPW |
|---|---|---|---|---|---|---|---|
| Program | | V1 | 0 | V2 | V2 | 0 | 0 |
| Read | | 0 | 0 | V3 | V3 | 0 | 0 |
| Erasure | Stage1 | 0 | 0 | 0 | 0 | V2 | 0 |
| | Stage2 | 0 | −V2 | 0 | 0 | V2 | 0 |

The voltage values V1-V3 are different from each other. In some embodiments, the voltage value V2 is larger than the voltage value V1, and the voltage value V1 is larger than the voltage value V3. For example, according to some embodiments, the voltage value V1 is about 4 volts, the voltage value V2 is about 8 volts and the voltage value V3 is about 2 volts.

The configurations of FIG. 1 to FIG. 4 are given for illustrative purposes. Various implements are within the contemplated scope of the present disclosure. For instance, in some embodiments, the voltage values V1 to V3 are not equal to 4 volts, 8 volts and 2 volts respectively. In other embodiments, the voltage values V1 and V2 are in a range from about 3 to 8 volts. In some other embodiments, the regions which are originally P-conducting type may be formed into N-conducting type, and meanwhile the regions which are originally N-conducting type may be formed into P-conducting type.

Reference is made to FIG. 3, FIG. 4 and the table 1, according to some embodiments, during the program operation, the bit line voltage VBL, the erasure voltage VEL and the voltage VPW applied to the well 104 are all grounded (about 0 volts), the selecting voltage VSG has the voltage value V1 (e.g., 4 volts), and the source line voltage VSL and the voltage VNW have the voltage value V2 (e.g., 8 volts). Under such configurations, due to the electric field in the well 102, the electrons in the channel region under the floating gate structure 220 gain kinetic energy, the gate dielectric layer 221 is tunneled by the electrons (also referred to as hot carriers) and the electrons are injected into the floating gate structure 220. The electric potential of the floating gate structure 220 changes in response to the change in the electron concentration, and the situation may be referred to as corresponding to the first storage state (e.g., logic value 1) of the memory device 10. By contrast, when the electrons are released from the floating gate structure 220 and the electron concentration is reduced, the situation may be referred to as corresponding to the second storage state (e.g., logic value 0) of the memory device 10.

During the read operation, except that the source line voltage VSL and the voltage VNW are the voltage value V3 (e.g., 2 volts), the other operating voltages are all 0 volts. Under such configurations, as shown in FIG. 3 and FIG. 4, the magnitude of the read current from the source line SL to the bit line BL depends on whether the floating gate structure 220 stores carriers (electrons) or not. Alternatively stated, the storage state of data in the memory device 10 may be known by the read current. For example, in some embodiments, when the memory device 10 is in the first storage state (logic value 1), the read current (e.g., high current) is larger than a reference current value (e.g., 5 μA). In comparison, when the memory device 10 is in the second storage state (logic value 0), the read current (e.g., low current, 0.1 μA) is far lower than the reference current value.

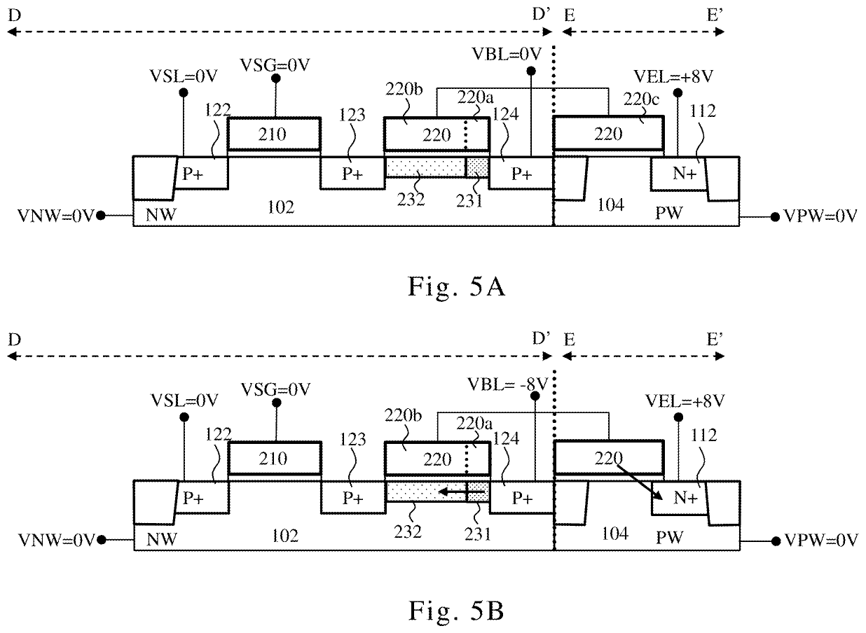

Reference is made to FIG. 5A to FIG. 5B. FIG. 5A to FIG. 5B are perspective diagrams respectively corresponding to the memory device 10 in FIG. 1 in stage 1 and stage 2 under the erasure operation according to one embodiment.

During the erasure operation that changes the storage state of the memory device 10, according to the effect of Fowler-Norheim tunneling, the electrons in the floating gate structure 220 are affected by the electric field from the gate dielectric layer 221 and released into the erasure signal line EL, in which the electric field from the gate dielectric layer 221 are related to the floating gate coupling voltage of the floating gate structure 220 and the voltage of the erasure signal line EL. Alternatively stated, during the erasure operation, the voltage difference between the voltage on the erasure signal line EL and the floating gate coupling voltage may meet the voltage VFN that brings about the effect of Fowler-Norheim tunneling by properly setting the operation voltages in the table 1. Accordingly, the electron concentration in the floating gate structure 220 is reduced and the memory device 10 is transformed from the first storage state to the second storage state (e.g., logic value 0). In some embodiments, the floating gate coupling voltage VFG is referred to that the bias voltage of all electrodes of the memory device 10 is coupled to the floating gate structure 220 and able to be expressed in the formula (1):

$$VFG = {CR}_{VT 1} \times VBL + {CR}_{VT 2} \times VNW + {CR}_{EL} \times VEL + Q / C , \qquad ( 1 )$$

where CR_{VT1} represents the capacitive coupling ratio of the floating gate structure 220 to the doped region 124, CR_{VT2} represents the capacitive coupling ratio of the floating gate structure 220 to the well 102, CR_{EL} represents the capacitive coupling ratio of the floating gate structure 220 to the doped region 112, Q represents the total charge of the floating gate structure 220, and C represents the total capacity between the floating gate structure 220, the well 102, the doped region 124 and the doped region 112.

In some embodiments, as shown in FIG. 5A to FIG. 5B, the floating gate structure 220 may include a gate structure 220a and a gate structure 220b that are above the well 102 (the distance between the gate structure 220b and the doped region 124 is larger than the distance between the gate structure 220a and the doped region 124), and a gate structure 220c above the well 104. The capacitive coupling ratios CR_{VT1} and CR_{VT2} may be respectively referred to as the capacitive coupling ratios of the gate structure 220a and the gate structure 220b, the capacitive coupling ratio CR_{EL} may be referred to as the capacitive coupling ratio of the gate structure 220c. In some embodiments, the capacitive coupling ratios CR_{VT1}, CR_{VT2} and CR_{EL} are different from each other. In another embodiments, the capacitive coupling ratio CR_{VT1} is smaller than the capacitive coupling ratio CR_{VT2}, and the capacitive coupling ratio CR_{EL} is smaller than the capacitive coupling ratio CR_{VT1}. For instance, the capacitive coupling ratio CR_{VT1} is about 0.3, the capacitive coupling ratio CR_{VT2} is about 0.65 and the capacitive coupling ratio CR_{EL} is 0.05. The configuration of values of the capacitive coupling ratio is provided for the descriptive purpose. Various embodiments are included in the expected category of one embodiment of the present disclosure.

As shown in table 1, in some embodiments, the erasure operation includes two stages: stage 1 and stage 2. The channel regions 231 and 232 have different critical voltages of channel formation, in which the critical voltage of channel formation refers to as the floating gate coupling voltage VFG of a region corresponding to where above the channel region when the channel is formed to transport carriers (e.g., electrons). In some embodiments, the absolute value of the critical voltage of channel formation of the channel region 231 is smaller than the absolute value of the critical voltage of channel formation of the channel region 232.

For example, based on the previously discussed embodiments, table 1 and what as shown in FIG. 5A, at the stage 1 of the erasure operation, the voltage VNW and the bit line voltage VBL are both 0 and the erasure voltage VEL is V2 (8 volts). The channel region 231 is formed to transport carriers. According to the formula (1), the floating gate coupling voltage VFG at this moment may be expressed as follows:

$$VFG = 0.3 \times 0 + 0.65 \times 0 + 0.05 \times 8 = 0.4$$

For the sake of brevity and the easiness of understanding the present disclosure, the discussion of the influence of the total charge Q is omitted. Based on the above discussion, the channel region 231 is formed and may be referred to as having the critical voltage of channel formation of 0.4 volts.

Next, reference is made to table 1 and FIG. 5B. At the stage 2 of the erasure operation, the voltage VNW is 0 and the absolute values of the bit line voltage VBL and the erasure voltage VEL are the same. Specifically, the bit line voltage VBL is −V2 (−8 volts) and the erasure voltage VEL maintains at V2 (8 volts). The channel region 232 is formed to transport carriers. According to the formula (1), the floating gate coupling voltage VFG at this moment may be expressed as follows:

$$VFG = 0.3 \times ( - 8 ) + 0.65 \times 0 + 0.05 \times 8 = - 2 .$$

Based on the above discussion, the channel region 232 is formed sequentially after the formation of the channel region 231, and the channel region 232 may be referred to as having the critical voltage of channel formation of −2 volts.

With continued reference to FIG. 5B, based on the above embodiments, due to the formation and conduction of the channel regions 231 and 232, the channel region 232 is enabled to have the bit line voltage (i.e., −8 volts). In this condition, the voltage VNW in the formula (1) for calculating the floating gate coupling voltage VFG is replaced by the bit line voltage VBL, and the floating gate coupling voltage VFG may be expressed as follows:

$$VFG = 0.3 \times ( - 8 ) + 0.65 \times ( - 8 ) + 0.05 \times 8 = - 7.2$$

The potential difference ΔV between the erasure voltage VEL and the floating gate coupling voltage VFG may be expressed as follows:

$$ΔV = VEL - VFG = 8 - ( - 7.2 ) = 15.2$$

In some embodiments, the voltage VFN that can bring about the effect of Fowler-Norheim tunneling is about 15 volts. The above potential difference ΔV is already larger than the voltage VFN. Therefore, based on the above configurations, the electrons in the floating gate structure 220 tunnel through the gate dielectric layer 221, enter into the well 104 and the doped region 112, and are released into the erasure signal line EL.

In some memories, in order to make electrons in the floating gate tunnel through the gate dielectric layer during the erasure operation and be released to the erasure signal line, the erasure signal line should be applied with at least 15 volts. However, such configurations of high voltage increase the risk of N+/PW junction breakdown at the interface between the doped region (e.g., n-type), coupled to the erasure signal line, and the well of p-type where the doped region is located, making the reliability of the memory device lowered. In another methods of manufacturing, the thickness of the gate dielectric layer near the doped region coupled to the erasure signal line may be reduced by one additional layer of mask, and the voltage (e.g., 12 volts) needed to be applied to the erasure signal line is slightly lowered. But this method may increase the cost of manufacturing memories and reduce the speed of manufacture.

Compared with the above methods, by the implementations shown through FIG. 1 to FIG. 5B, the present disclosure provides two regions of different critical voltages of channel formation. During the erasure operation, the floating gate structure 220 may be more easily coupled to the bit line voltage VBL through the channel region 231 before the electrons are fully released to the erasure signal line EL. Alternatively stated, the efficiency of coupling of the bit line voltage VBL to the floating gate structure 220 is increased, and, meanwhile based on the above discussions, the erasure voltage is also largely reduced to about 8 volts. In this way, not only may the overall efficiency of coupling be increased to improve the product efficacy but also the chances of junction breakdown between the doped region of n-type and the well of p-type may be reduced to improve the product reliability.

The configurations of FIG. 5A to FIG. 5B are given for illustrative purposes. The embodiments of FIG. 5A to FIG. 5B are within the contemplated scope of the present disclosure. For instance, in some embodiments, the absolute values of the bit line voltage VBL and the erasure voltage VEL are different.

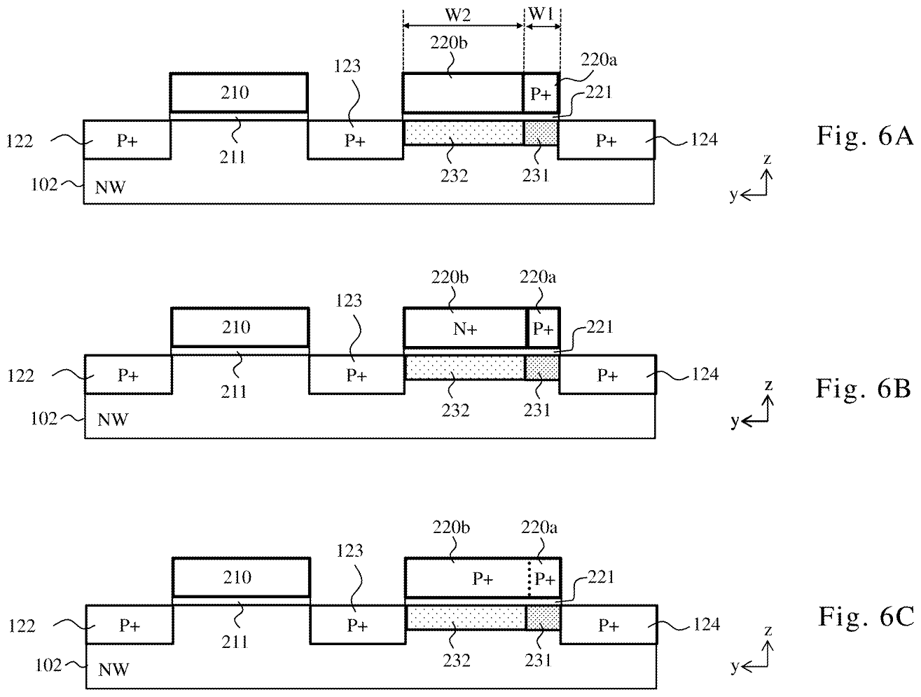

Next, reference is made to FIG. 6A to FIG. 6C for the discussions of various embodiments of the gate structure 220a and the gate structure 220b of the floating gate structure 220. FIG. 6A to FIG. 6C are perspective diagrams corresponding to a portion of the memory device in FIG. 1 according to various embodiments. With respect to the embodiments of FIG. 1 to FIG. 5B, like elements in FIG. 6A to FIG. 6C are designated with the same reference numbers for ease of understanding. For the sake of simplicity, the specific operations of the similar devices described in detail in the above paragraphs are omitted, unless the introduction of the collaborative relation to the devices in FIG. 6A is needed.

As shown in FIG. 6A, the gate structure 220a and the gate structure 220b are respectively above the channel region 231 and the channel region 232, and have different widths W1 and W2 along the y direction. In some embodiments, the width W2 is greater than the width W1.

In some embodiments, the gate structure 220a and the gate structure 220b have different doping concentrations or different conducting types, and accordingly have different capacitive coupling ratios. As shown in FIG. 6A, the gate structure 220a is a doped region of p-type and the gate structure 220b is an undoped region (e.g., materials of α-Si or polycrystalline). In the embodiment in FIG. 6B, the gate structure 220a is a doped region of p-type and the gate structure 220b is a doped region of n-type.

In the embodiment in FIG. 6C, the gate structure 220a and the gate structure 220b have the same doping concentration and conducting type (p-type). But the channel region 231 and the channel region 232 have different doping concentrations, so that, effectively, the gate structure 220a and the gate structure 220b have different capacitive coupling ratios. In some embodiments, the doping concentration is about 10¹¹ cm⁻²˜10¹⁵ cm⁻². The values of doping concentration are given for the descriptive purposes. Various embodiments are within the contemplated scope of one embodiment of the present disclosure.

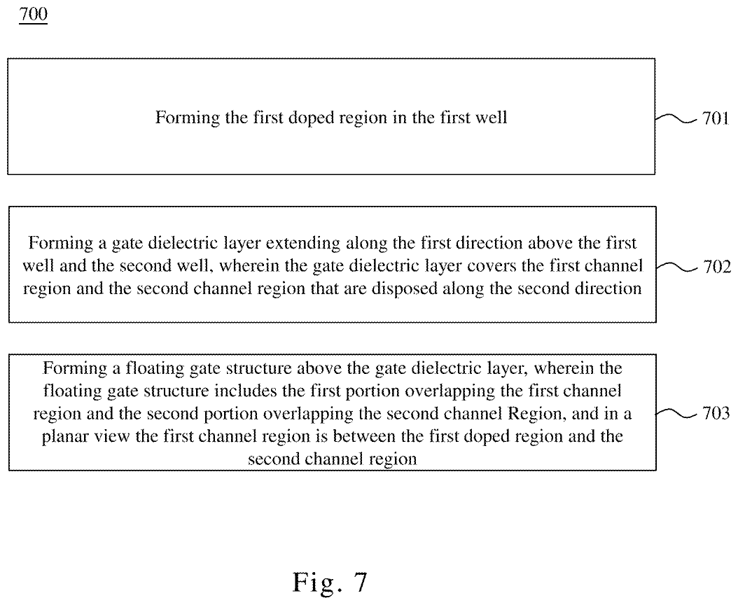

Reference is made to FIG. 7. FIG. 7 is a flowchart of a manufacturing method 700 of the memory device according to one embodiment. It should be noted that extra operations may be provided before, during or after the steps indicated in FIG. 7 and some of the following operations may be replaced or cancelled to obtain embodiments beyond the scope of the manufacturing method 700 of the memory device. The manufacturing method of the memory device includes the following step 701 to step 703 described in FIG. 7.

In step 701, as shown in FIG. 4, the doped region 124 is formed in the well 102.

In some embodiments, the manufacturing method 700 of the memory device further includes the formation of the channel region 232 in the well 102, in which the doping concentrations of the channel region 232 and the well 102 are different. For example, in some embodiments, the range of doping concentration of the channel region 232 is about 10¹¹ cm⁻²˜10¹⁵ cm⁻², and the range of doping concentration of the well 102 is about 10⁸ cm⁻²˜10¹⁴ cm⁻². The values of doping concentration are provided for the descriptive purpose. Various embodiments are within the contemplated scope of one embodiment of the present disclosure.

In step 702, as shown in FIG. 4, the gate dielectric layer 221 extending along the x direction is formed above the well 102 and the well 104. In some embodiments, the gate dielectric layer 221 covers the channel region 231 and the channel region 232 that are disposed in a direction different from the y direction.

In step 703, as shown in FIG. 4, the floating gate structure 220 is formed above the gate dielectric layer 221. In some embodiments, the floating gate structure 220 include, in a planar view, the first portion overlapping the channel region 231 and the second portion overlapping the channel region 232, which are, for instance, the gate structure 220a and the gate structure 220b respectively. In the planar view, the channel region 231 is between the doped region 124 and the channel region 232.

In some embodiments, the capacitive coupling ratio (e.g., CR_{VT1}) that the first portion of the floating gate structure 220 is relative to the doped region 124 is different from the capacitive coupling ratio (e.g., CR_{VT2}) that the second portion of the floating gate structure 220 is relative to the well 102.

In some embodiments, the first portion of the floating gate structure 220 may be P-conducting type as the gate structure 220a in the embodiment shown in FIG. 6A, and the second portion of the floating gate structure 220 may be an undoped region as the gate structure 220b in the embodiment shown in FIG. 6A.

In some other embodiments, the first portion of the floating gate structure 220 may be P-conducting type as the gate structure 220a in the embodiment shown in FIG. 6B, and the second portion of the floating gate structure 220 may be N-conducting type as the gate structure 220b in the embodiment shown in FIG. 6A.

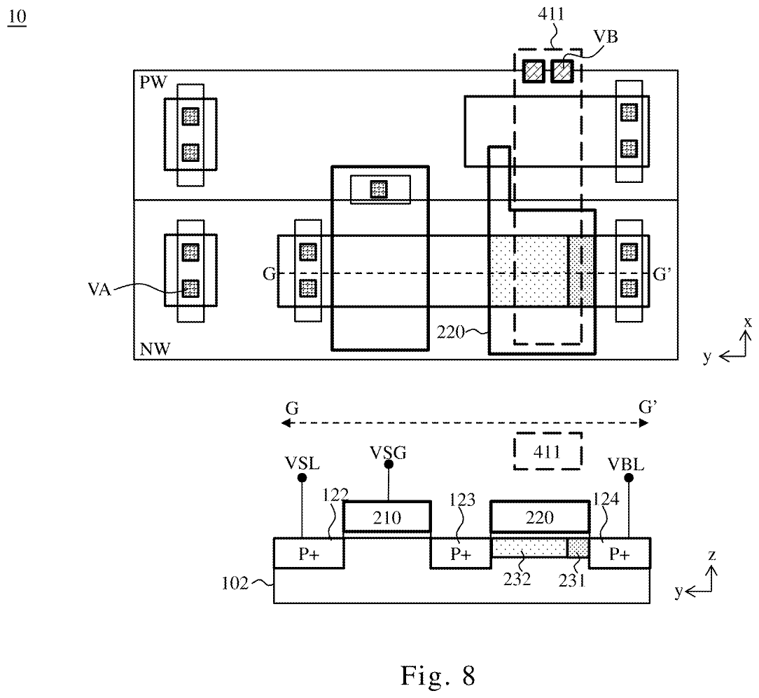

Reference is made to FIG. 8. FIG. 8 is a perspective diagram corresponding to one portion of the memory device 10 in FIG. 1 along line GG′ according to another embodiment. As shown in FIG. 8, the memory device 10 further includes a conducting track 411. The conducting track 411 extends along the x direction, and receives or transmits signals through a via VB. The conducting track 411 is further disposed along the z direction and above the floating gate structure 220, and separated from the floating gate structure 220. In some embodiments, the conducting track 411 is disposed in the fourth semiconducting layer (for example, metal one layer) above the third semiconducting layer where the conducting segments 311-317 are located, and includes conducting materials.

In some embodiments, when the conducting track 411 is applied with a negative voltage, the coupling effect of the conducting track 411 and the floating gate structure 220 may improve the efficiency of erasure operation and increase the speed of release of the carriers in the floating gate structure 220.

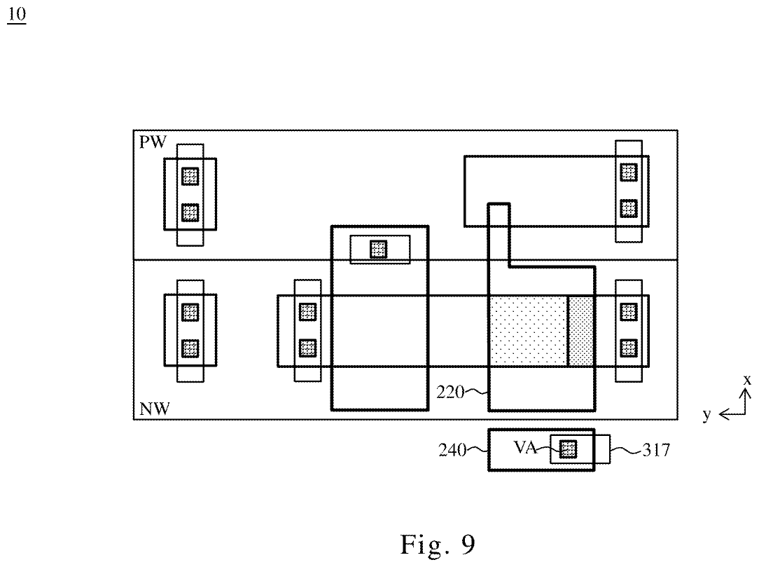

Reference is made to FIG. 9. FIG. 9 is a schematic diagram corresponding to the memory device 10 in a planar view in FIG. 1 according to another embodiment. As shown in FIG. 9, the memory device 10 further includes the gate structure 240 and the conducting segment 317. The gate structure 240 extends along the y direction and is separated from the floating gate structure 220 by a distance along the x direction. The conducting segment 317 is configured with respect to, for example, the conducting segments 311-316.

In some embodiments, when the gate structure 240 receives negative voltage through the conducting segment 317, and the via VA coupled between the gate structure 240 and the conducting segment 317. The coupling effect of the gate structure 240 and the floating gate structure 220 may improve the efficiency of erasure operation and increase the speed of release of the carriers in the gate structure 220.

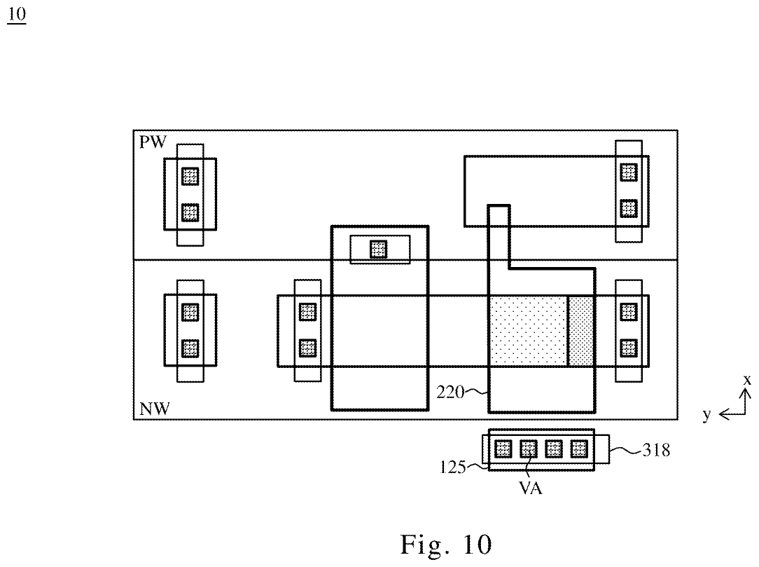

FIG. 10 is a schematic diagram corresponding to the memory device 10 in a planar view in FIG. 1 according to another embodiment. As shown in FIG. 10, the memory device 10 further includes a conducting structure 125 and a conducting segment 318. The conducting structure 125 extends along the y direction and is separated from the floating gate structure 220 by a distance along the x direction. In some embodiments, the conducting structure 125 includes metal-on-device MD configured to receive or transmit signals. In some embodiments, the metal-on-device MD is disposed between the first semiconducting layer where the active region 120 is located and the third semiconducting layer where the conducting segments 311-318 are located. The conducting segment 318 may be disposed in relation to the conducting segments 311-317.

In some embodiments, when the conducting structure 125 receives negative voltages through the conducting segment 318, and the vias VA coupled between the gate structure 240 and the conducting segment 317. The coupling effect between the conducting structure 125 and the floating gate structure 220 may improve the efficiency of erasure operation and increase the speed of release of the carriers in the gate structure 220.

As above, the memory device and the manufacturing method of the same in the present disclosure provide a device with different regions corresponding to the floating gate structure. By the configurations above, the coupling effect of the bit line and the floating gate structure is enhanced, and the voltage needed to apply to the erasure signal line during the erasure operation is reduced. The efficacy and reliability of the memory device is improved.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a first well;
a first doped region disposed in the first well and coupled to an erasure signal line, and the first doped region having a first conducting type;
a second doped region disposed in a second well and coupled to a bit line, and the second doped region having a second conducting type; and
a floating gate structure crossing above the first well and the second well, and the floating gate structure comprising:
a first gate structure having a first capacitive coupling ratio and a second gate structure, wherein the first gate structure and the second gate structure are disposed above the second well, and the second gate structure has a second capacitive coupling ratio different from the first capacitive coupling ratio.

2. The memory device of claim 1, wherein the first gate structure has the second conducting type and the second gate structure is an undoped region.

3. The memory device of claim 1, wherein the first gate structure has the second conducting type and the second gate structure has the first conducting type.

4. The memory device of claim 1, further comprising:
a first channel region under the first gate structure; and
a second channel region under the second gate structure, wherein the first channel region and the second channel region have different doping concentrations.

5. The memory device of claim 1, wherein a distance between the first gate structure and the first doped region is smaller than a distance between the second gate structure and the first doped region, and the first capacitive coupling ratio is smaller the second capacitive coupling ratio.

6. The memory device of claim 5, wherein the floating gate structure further comprises:
a third gate structure disposed above the first well and having a third capacitive coupling ratio, wherein the third capacitive coupling ratio is smaller than the first capacitive coupling ratio.

7. The memory device of claim 1, wherein along a first direction, the first gate structure has a first width and the second gate structure has a second width different from the first width.

8. The memory device of claim 1, wherein during an erasure operation, absolute values of a voltage at the erasure signal line and a voltage at the bit line are the same.

9. A memory device, comprising:
an erasure gate region comprising:
a first well; and
a floating gate transistor comprising:
a first channel region and a second channel region that are disposed along a first direction; and
a floating gate structure disposed above the first channel region and the second channel region, and the floating gate structure extending above the first well along a second direction different from the first direction, wherein the first channel region and the second channel region have different critical voltages of channel formation.

10. The memory device of claim 9, wherein an absolute value of the critical voltage of channel formation of the first channel region is smaller than an absolute value of the critical voltage of channel formation of the second channel region.

11. The memory device of claim 9, wherein an area of the first channel region under the floating gate structure is smaller than an area of the second channel region under the floating gate structure.

12. The memory device of claim 9, wherein the floating gate structure comprises:
a first gate structure disposed above the first channel region and having a first width along the first direction; and
a second gate structure disposed above the second channel region and having a second width greater than the first width along the first direction, wherein the first gate structure and the second gate structure have different doping concentrations.

13. The memory device of claim 12, wherein the floating gate transistor further comprises:
a first doped region disposed in a second well and configured to receive a bit line voltage, wherein the first channel region is disposed between the first doped region and the second channel region, wherein the first doped region and the first gate structure have the same conducting type.

14. The memory device of claim 13, wherein the first gate structure has a first conducting type and the second gate structure has a second conducting type different from the first conducting type.

15. The memory device of claim 13, wherein the erasure gate region further comprises:
a second doped region disposed in the first well and configured to receive an erasure voltage, wherein during an erasure operation, the erasure voltage is a positive voltage and the bit line voltage is a negative voltage.

16. The memory device of claim 9, wherein the first channel region and the second channel region have different doping concentrations.

17. The memory device of claim 9, wherein along the first direction, the first channel region has a first width and the second channel region has a second width greater than the first width.

18. A manufacturing method of a memory device, comprising following steps:
forming a first doped region in a first well;
forming a gate dielectric layer extending along a first direction on the first well and a second well, wherein the gate dielectric layer covers a first channel region and a second channel region that are disposed along a second direction which is different from the first direction; and
forming a floating gate structure on the gate dielectric layer, wherein the floating gate structure comprises:
in a planar view, a first portion overlapping the first channel region and a second portion overlapping the second channel region, and the first channel region being between the first doped region and the second channel region in the planar view, wherein a first capacitive coupling ratio of the first portion to the first doped region is different from a second capacitive coupling ratio of the second portion to the first well.

19. The manufacturing method of claim 18, wherein the first portion is P-conducting type and the second portion is N-conducting type.

20. The manufacturing method of claim 18, further comprising a following step:
forming a second doped region, which is different from the first well, as the second channel region in the first well.
